(19) United States
(12) Patent Application Publication
(10) Pub. No.: US 2014/0021619 A1
(43) Pub. Date: Jan. 23, 2014

(54) PAD STRUCTURE AND INTEGRATED CIRCUIT CHIP WITH SUCH PAD STRUCTURE

(71) Applicant: MEDIATEK INC., Hsin-Chu (TW)

(72) Inventor: Yu-Hua Huang, Hsinchu City (TW)

(73) Assignee: MEDIATEK INC., Hsin-Chu (TW)

(21) Appl. No.: 14/043,832

(22) Filed: Oct. 1, 2013

Related U.S. Application Data
(63) Continuation of application No. 12/912,777, filed on Oct. 27, 2010.
Application No. 12/912,777 is a continuation-in-part of application No. 12/729,224, filed on Mar. 22, 2010, now Pat. No. 8,278,733.
(60) Provisional application No. 61/290,405, filed on Dec. 28, 2009.

(51) Int. Cl. H01L 23/488

(52) U.S. Cl. CPC H01L 23/488
USPC 257/765

(57) ABSTRACT

An integrated circuit chip includes a substrate; at least one inter-metal dielectric layer over the substrate; a topmost metal layer overlying the inter-metal dielectric layer; a bonding pad in the topmost metal layer, the bonding pad comprising a central thinner portion and a peripheral thicker portion surrounding the central thinner portion; and a passivation layer covering the peripheral thicker portion.

### CROSS REFERENCE TO RELATED APPLICATIONS

This application is a continuation of U.S. application Ser. No. 12/912,777 filed on Oct. 27, 2010, which itself is a continuation-in-part of U.S. application Ser. No. 12/729,224 filed on Mar. 22, 2010, which also claims the benefits from U.S. provisional application No. 61/290,405 filed on Dec. 28, 2009.

### BACKGROUND OF THE INVENTION

1. Field of the Invention

The present invention relates generally to a pad structure of integrated circuit chips. More particularly, the invention relates to an improved wire-bonding pad structure and an integrated circuit chip with such wire-bonding pad structure, which is capable of avoiding pad deformation or cracking during wire bonding.

2. Description of the Prior Art

An urgent demand for smaller and cheaper electronic products with increased functionality and performance exists. A major trend of circuit design is to incorporate as many circuit components into integrated circuit as possible, whereby cost per wafer can be reduced.

Integrated circuits are manufactured by forming semiconductor devices in the surface of silicon wafers. A multi-level interconnection is formed over the devices, contacting their active elements, and wiring them together to create the desired circuits. The wiring layers are formed by depositing a dielectric layer over the devices, patterning and etching contact openings into this layer, and then depositing conductive material into the openings. A conductive layer is applied over the dielectric layer and patterned to form wiring interconnection between the device contacts, thereby creating a first level of basic circuitry. The circuits are then further interconnected by utilizing additional wiring levels laid out over additional dielectric layers with conductive via. Depending upon the complexity of the overall integrated circuit, several levels of wiring interconnections are used. On the uppermost level the wiring is terminated at metal pads to which the chip's external wiring connections are bonded.

In some cases, the uppermost level the wiring may be a thick aluminum layer. Metal pads such as wire-boding pads and RF devices such as an integrated inductors, MOM capacitors, resistors, or redistribution layer (RDL) may be formed concurrently in the thick aluminum layer. However, the thick aluminum layer leads to pad deformation, which occurs due to the stress exerted thereon during wire bonding. The deformed bonding pad may also cause the fracture defects in the passivation layer covering the periphery of the bonding pad, and potential pad-to-pad bridging. To cope with these problems, the size of each pad, pad opening and/or the space between two pads are typically enlarged. However, increase of the size of each pad, pad opening and the pad pitch results in larger chip size and higher cost.

### SUMMARY OF THE INVENTION

It is one object of the invention to provide an improved bonding pad structure in an integrated circuit chip to solve the problem of bonding pad deformation.

According to one embodiment of the invention, an integrated circuit chip includes a substrate; at least one inter-metal dielectric layer over the substrate; a topmost metal layer overlying the inter-metal dielectric layer; a bonding pad in the topmost metal layer, the bonding pad comprising a central thinner portion and a peripheral thicker portion surrounding the central thinner portion; and a passivation layer covering the peripheral thicker portion.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, cross-sectional diagram illustrating portions of an integrated circuit chip in accordance with one embodiment of this invention;

FIG. 2 is a schematic, cross-sectional diagram illustrating portions of an integrated circuit chip in accordance with one embodiment of this invention; and

FIG. 3 is a schematic, cross-sectional diagram illustrating portions of an integrated circuit chip in accordance with another embodiment of this invention.

### DETAILED DESCRIPTION

The preferred embodiments of this invention will now be explained with the accompanying figures. Throughout the specification and drawings, the symbol “Mₙ” refers to the topmost level of the metal layers, such as an aluminum redistribution layer (RDL), fabricated in the integrated circuit chip, while “Mₙ₋₁” refers to the metal layer that is one level lower than the topmost metal layer and so on, wherein, preferably, n ranges between 2 and 10 (n=2-10), but not limited thereto. The symbol “V” refers to the via plug connecting two adjacent metal layers. For example, V₅ refers to the via plug interconnecting M₅ to M₆.

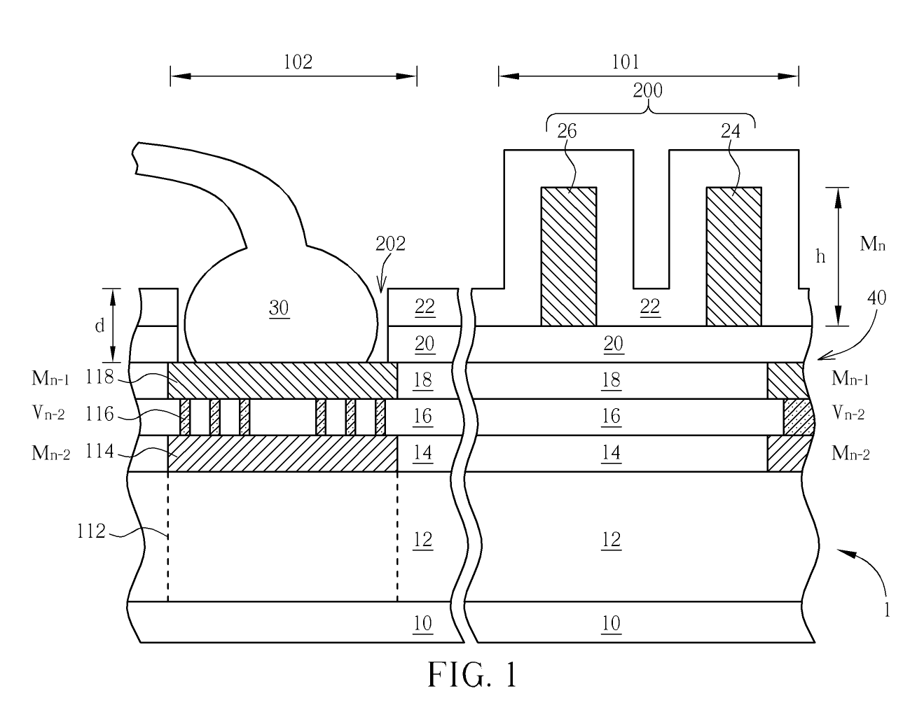

Please refer to FIG. 1. FIG. 1 is a schematic, cross-sectional diagram illustrating portions of an integrated circuit chip 1 in accordance with one embodiment of this invention. It is understood that the layers or elements in the figures are not drawn to scale and are modified for the sake of clarity. The integrated circuit chip 1 may include an RF integrated circuit incorporating a top metal layer (Mₙ) for an RF device, such as inductor or any other devices suitable for RF circuit. The top metal layer (Mₙ) for the RF device may be an aluminum layer, a copper layer or a copper alloy layer, preferably, aluminum layer.

The top metal layer could reduce parasitic losses and hence improves the quality factor Q of the RF integrated circuit. In this embodiment, thickness of the top metal layer is not less than 0.5 micrometer. In some embodiments, the top metal layer has a thickness not less than 1.0 micrometer. In some further embodiments, the top metal layer has a thickness not less than 3.0 micrometer.

As shown in FIG. 1, the integrated circuit chip 1 comprises a substrate 10 such as a silicon substrate. The substrate 10 may be any suitable semiconductor substrate such as SiGe substrate or silicon-on-insulator (SOI) substrate. A base layer 12 including but not limited to a device layer such as MOS or bipolar devices and at least one inter-layer dielectric (ILD) is formed on the substrate 10. For the sake of simplicity, the interconnection including wiring and contact/via in the base layer 12 are not shown. A plurality of inter-metal dielectric (IMD) layers 14, 16, 18 and 20 are provided on the base layer 12. Each of the plurality of IMD layers 14, 16, 18 and 20 may include, but not limited to, silicon oxide, silicon nitride, silicon carbide, silicon oxy-nitride, low-k or ultra low-k (ULK) materials such as organic (e.g., SiLK) or inorganic (e.g., HSQ), or a combination thereof. A passivation layer 22 overlies at least a portion of the IMD layer 20. The passivation layer 22 may be silicon oxide, silicon nitride, silicon carbide, silicon oxy-nitride, polyimide, a combination thereof or the like. According to this embodiment, the passivation layer 22 has a thickness of about 0.5-6.0 micrometers, but should be not limited thereto.

A metal interconnection 40 such as Mₙ₋₂, Vₙ₋₂ and Mₙ₋₁ may be fabricated in the respective IMD layers 14, 16 and 18 respectively. An RF device, such as an inductor 200, which may comprise a first winding 24 and a second winding 26 in proximity to the first winding 24, is fabricated in the top metal layer (Mₙ) within the inductor forming region 101 of the integrated circuit chip 1. According to the embodiment of this invention, the top metal layer (Mₙ) has a thickness h that is not less than 0.5 micrometer. In some embodiments, the top metal layer has a thickness not less than 1.0 micrometer. In some further embodiments, the top metal layer has a thickness not less than 3.0 micrometer. The sidewalls and top surfaces of the first winding 24 and the second winding 26 of the inductor 200 could be covered with the passivation layer 22. Although the embodiment takes an inductor as an example, the invention is not intended to be limited thereto. It is to be understood that other RF devices such as an MOM capacitor or a resistor may be formed from the top metal layer Mₙ. Further, the top metal layer Mₙ may be used to form a redistribution layer (RDL).

According to the embodiment of this invention, the metal layer Mₙ₋₁ in which at least one bonding pad 118 is formed could be made of aluminum, while the metal layer Mₙ₋₂ could be formed by conventional copper damascene methods such as single damascene methods or dual damascene methods. For example, the metal layer Mₙ₋₂ could be formed by single damascene methods, while the metal layer Mₙ₋₁ and the integral via plug layer Vₙ₋₂ could be formed by conventional aluminum process. Besides, Mₙ₋₂ could be made of aluminum. As known in the art, the copper damascene methods provide a solution to form a conductive wire coupled with an integral via plug without the need of dry etching copper. Either a single damascene or a dual damascene structure may be used to connect devices and/or wires of an integrated circuit.

The integrated circuit chip 1 comprises a bonding pad forming region 102. At least one bonding pad 118 is formed in the metal layer Mₙ₋₁ within the bonding pad forming region 102. The metal layer Mₙ₋₁ could be thinner than the top metal layer (Mₙ) . For example, the metal layer Mₙ₋₁ may have a thickness of about 0.2-1 micrometers. An opening 202 is formed in the passivation layer 22 and the IMD layer 20 to expose at least a portion of the top surface of the bonding pad 118 such that a bond wire 30 may be stuck to the bonding pad 118 in a package assembly stage. The opening 202 may have a depth of about 0.8-6.0 micrometers. According to the embodiment of this invention, the bonding pad 118 is preferably an aluminum pad, but not limited thereto.

Optionally, supporting structures 114 and 116 may be formed underneath the bonding pad 118. The supporting structures 114 and 116 may be in any suitable shapes and configurations to provide adequate mechanical support for the bonding pad 118 during the wire boding process. For example, the supporting structure 114 may be a dummy metal plate that is fabricated in the metal layer Mₙ₋₂, while the supporting structure 116 may be a plurality of via plugs connecting the supporting structure 114 with the bonding pad 118. In addition, within the area 112 under the bonding pad 118, active circuit, circuit elements or interconnections (not shown) may be formed.

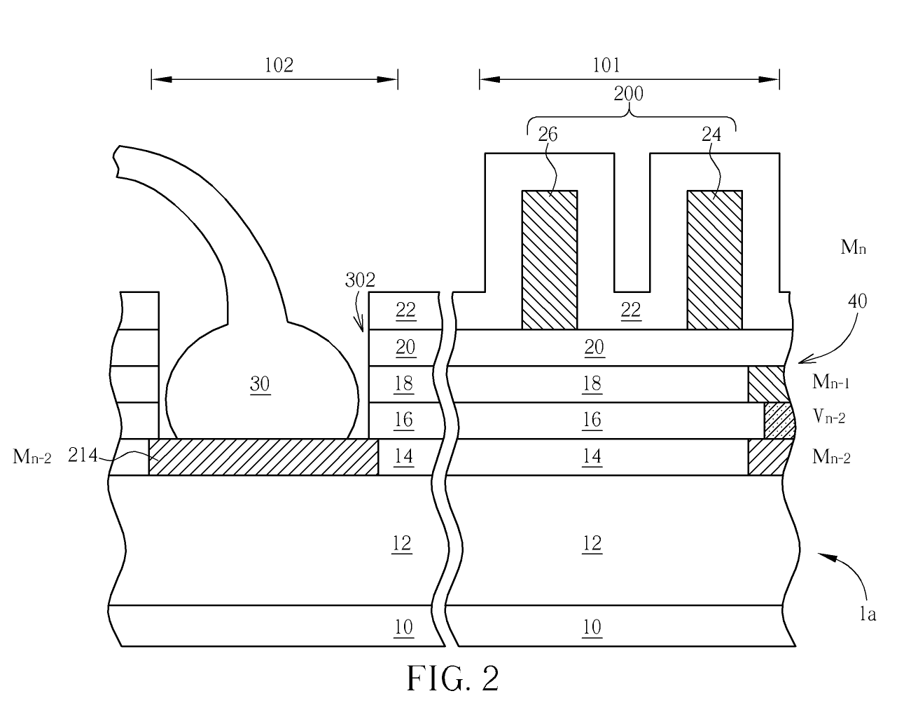

FIG. 2 is a schematic, cross-sectional diagram illustrating portions of an integrated circuit chip 1a in accordance with one embodiment of this invention, wherein like layers, regions or elements are designated by like numeral numbers. It is understood that the layers or elements in the figures are not drawn to scale and are modified for the sake of clarity. As shown in FIG. 2, likewise, the integrated circuit chip 1a comprises a substrate 10. A base layer 12 and a plurality of IMD layers 14, 16, 18 and 20 are provided on the substrate 10. Each of the plurality of IMD layers 14, 16, 18 and 20 may include, but not limited to, silicon oxide, silicon nitride, silicon carbide, silicon oxy-nitride, low-k or ultra low-k (ULK) materials such as organic (e.g., SiLK) or inorganic (e.g., HSQ), or a combination thereof. A passivation layer 22 overlies at least a portion of the IMD layer 20. The passivation layer 22 may be silicon oxide, silicon nitride, silicon carbide, silicon oxy-nitride, polyimide, a combination thereof or the like. According to this embodiment, the passivation layer 22 has a thickness of about 0.5-6.0 micrometers, but should be not limited thereto.

A metal interconnection 40 such as Mₙ₋₂, Vₙ₋₂ and Mₙ₋₁ may be fabricated in the respective IMD layers 14, 16, 18 and 20. An RF device, such as an inductor 200 which may comprise a first winding 24 and a second winding 26 in close proximity to the first winding 24, is fabricated in the top metal layer (Mₙ) within the inductor forming region 101 of the integrated circuit chip 1a. According to the embodiment of this invention, the top metal layer (Mₙ) has a thickness h that is not less than 0.5 micrometers. In some embodiments, the top metal layer has a thickness not less than 1.0 micrometer. In some further embodiments, the top metal layer has a thickness not less than 3.0 micrometer. The sidewalls and top surfaces of the first winding 24 and the second winding 26 of the inductor 200 could be covered with the passivation layer 22.

The integrated circuit chip 1a further comprises a bonding pad forming region 102. At least one bonding pad 214 can be formed in any metal layer that is lower than the top metal layer Mₙ, for example, the metal layer Mₙ₋₂, within the bonding pad forming region 102. An opening 302 is formed in the passivation layer 22 and the IMD layers 16, 18 and 20 to expose at least a portion of the top surface of the bonding pad 214 such that a bond wire 30 may be stuck to the bonding pad 214 in a package assembly stage. The opening 302 may have a depth of about 1.0-8.0 micrometers. It is noteworthy that a supporting structure under the bonding pad 214 can be omitted, as shown in FIG. 2.

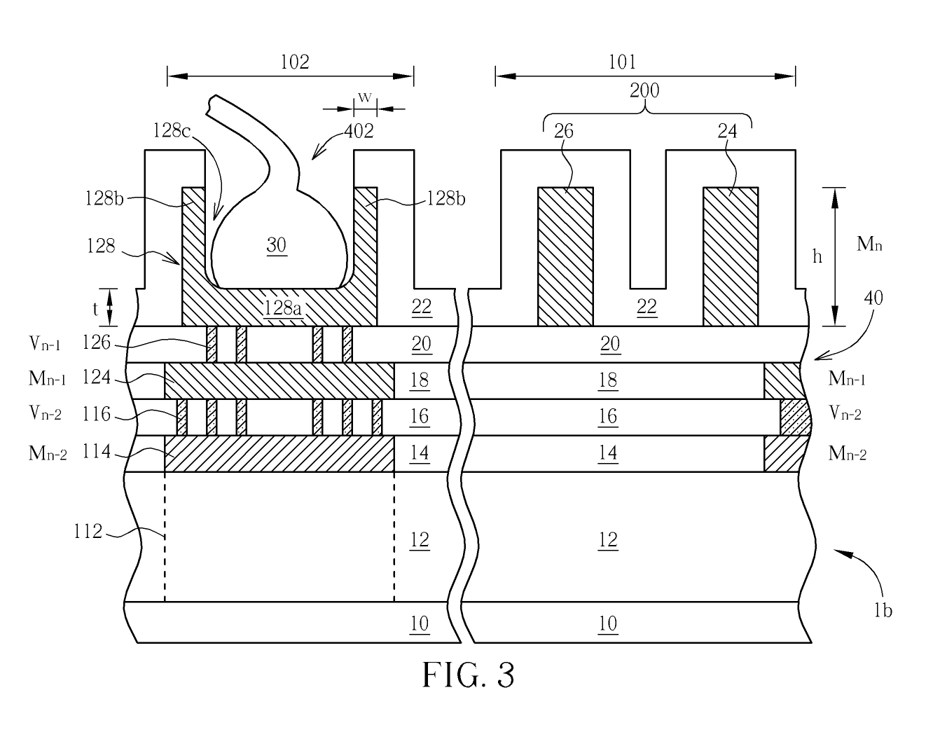

FIG. 3 is a schematic, cross-sectional diagram illustrating portions of an integrated circuit chip 1b in accordance with another embodiment of this invention, wherein like layers, regions or elements are designated by like numeral numbers. As shown in FIG. 3, the integrated circuit chip 1b comprises a substrate 10. A base layer 12 and a plurality of IMD layers 14, 16, 18 and 20 are provided on the substrate 10. Each of the plurality of IMD layers 14, 16, 18 and 20 may include, but not limited to, silicon oxide, silicon nitride, silicon carbide, silicon oxy-nitride, low-k or ultra low-k (ULK) materials such as organic (e.g., SiLK) or inorganic (e.g., HSQ), or a combination thereof. A passivation layer 22 can overly at least a portion of the IMD layer 20. The passivation layer 22 may be silicon oxide, silicon nitride, silicon carbide, silicon oxy-nitride, polyimide, a combination thereof or the like. According to this embodiment, the passivation layer 22 has a thickness of about 0.5-6.0 micrometers, but should be not limited thereto.

A metal interconnection 40 such as Mₙ₋₂, Vₙ₋₂, Mₙ₋₁ and Vₙ₋₁ may be fabricated in the IMD layers 14, 16, 18 and 20 respectively. In this embodiment, an RF device, such as an inductor 200 which may comprise a first winding 24 and a second winding 26 in close proximity to the first winding 24, can be fabricated in the top metal layer (Mₙ) within the inductor forming region 101 of the integrated circuit chip 1b. In some embodiments, a redistribution layer (RDL) can be formed in the top metal layer (Mₙ). According to the embodiment of this invention, the top metal layer (Mₙ) can have a thickness h that is not less than 1.0 micrometer The sidewalls and top surfaces of the first winding 24 and the second winding 26 of the inductor 200 could be covered with the passivation layer 22.

The integrated circuit chip 1b further comprises a bonding pad forming region 102. At least one bonding pad 128 can be formed in the top metal layer Mₙ within the bonding pad forming region 102. The bonding pad 128 can be utilized for wire-bonding. According to the embodiment of this invention, the bonding pad 128 and the inductor 200 are formed in the same metal layer, i.e., the top metal layer (Mₙ). In some case, an RDL wiring (not shown) may also be formed in the top metal layer (Mₙ). An opening 402 is formed in the passivation layer 22 to expose at least a portion of the top surface of the bonding pad 128 such that a bond wire 30 may be stuck to the bonding pad 128 in a package assembly stage. According to the embodiment of this invention, the bonding pad 128 is an aluminum pad, but not limited thereto. The top metal layer (Mₙ) can be an aluminum layer, but not limited thereto. In some cases that the integrated circuit chip 1b is fabricated by copper process and the bonding pad 128 is an aluminum pad, the metal layer Mₙ₋₁ may become the uppermost copper wiring layer or the final copper wiring layer. However, it is understood that the embodiment may be applicable to aluminum integrated circuit chips as well, wherein the metal interconnection is fabricated by aluminum processes, thus both the metal layers Mₙ and Mₙ₋₁ are aluminum layers.

According to the embodiment of this invention, the bonding pad 128 can be a bowl-shaped bonding pad with a central thinner portion 128a and a peripheral thicker portion 128b surrounding the central thinner portion 128a. The head of the bond wire 30 may rest in a cavity 128c surrounded by the peripheral thicker portion 128b. To form the cavity 128c, an additional etching process or an over-etching step may be carried out after the opening 402 is formed to etch away a portion of the exposed bonding pad 128. In some cases, the sidewall of the opening 402 can be substantially aligned with an inner sidewall of the peripheral thicker portion 128b. In some cases, the sidewall of the opening 402 can be more outward than the inner sidewall of the peripheral thicker portion 128b. Further, an extra photo mask may not be required. It is understood that the cavity 128c and the bowl shape of the bonding pad 128 may be formed by dry etching, wet etching or any other suitable methods.

According to the embodiment of this invention, the peripheral thicker portion 128b has a thickness that is not more than or substantially identical to that of top metal layer (Mₙ), the inductor 200 or RDL wiring (not shown). The thickness of top metal layer (Mₙ), the inductor 200 or RDL wiring (not shown) can be, for example, not less than 1.0 micrometer. According to the embodiment of this invention, the central thinner portion 128a has a thickness t not more than 2 micrometers. According to the embodiment of this invention, a width w of the peripheral thicker portion 128b may be greater than 0.5 micrometers, for example, about 0.5-10 micrometers. The passivation layer 22 may cover the top surface of the peripheral thicker portion 128b. Since the bonding pad 128 has a reduced thickness and thus a reduced volume, pad deformation or cracking during wire bonding may be avoided. In addition, the peripheral thicker portion 128b may act as a dam that may counteract the stress exerted on the central thinner portion 128a.

Optionally, supporting structures 114, 116, 124 and 126 may be formed underneath the bonding pad 128. The supporting structures 114, 116, 124 and 126 may be in any suitable shapes and configurations to provide adequate mechanical support for the bonding pad 128 during the wire boding process. For example, the supporting structure 114 may be a dummy metal plate that is fabricated in the metal layer Mₙ₋₂, the supporting structure 116 may be a plurality of via plugs connecting the supporting structure 114 with the supporting structure 124, and the supporting structure 126 may be a plurality of via plugs connecting the supporting structure 124 with the bonding pad 128. In addition, within the area 112 under the bonding pad 118, active circuit, circuit elements or interconnections (not shown) may be formed. In an aluminum process, the supporting structure 126 may be may be a plurality of tungsten via plugs. In a copper process, the bonding pad 128 can be an aluminum pad, and the supporting structure 126 may be a plurality of aluminum via plugs formed integrally with the bonding pad 128.

It is to be understood that although the embodiments use wire-bonding pads as examples, this invention is also applicable to other types of pads such as bump pads, solder pads or RDL pads. The aforesaid RDL pads may be RDL flip-chip pads. The invention is not intended to be limited to wire-bonding pads and integrated circuit chips using the wire-bonding pads. Further, in a case that a RDL pad is also presented on the integrated circuit chip, the thickness t of the central thinner portion 128a of the bonding pad 128 may not be equal to a thinnest portion of the RDL pad.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An integrated circuit chip, comprising:
a substrate;
at least one inter-metal dielectric layer over the substrate;
a topmost metal layer overlying the inter-metal dielectric layer;
a bonding pad in the topmost metal layer, the bonding pad comprising a central thinner portion and a peripheral thicker portion surrounding the central thinner portion; and
a passivation layer covering the peripheral thicker portion.

2. The integrated circuit chip according to claim 1, wherein the passivation layer comprises an opening exposing the central thinner portion.

3. The integrated circuit chip according to claim 1, wherein the bonding pad is an aluminum pad.

4. The integrated circuit chip according to claim 1, wherein the topmost metal layer is a redistribution layer (RDL).

5. The integrated circuit chip according to claim 1, wherein the topmost metal layer has a thickness not less than 1 micrometer and the peripheral thicker portion has a thickness not more than the thickness of the topmost metal layer.

6. The integrated circuit chip according to claim 1, wherein the central thinner portion of the pad has a thickness not more than 2 micrometers.

7. The integrated circuit chip according to claim 1, wherein the bonding pad is a bowl-shaped pad.

8. The integrated circuit chip according to claim 7, wherein the peripheral thicker portion has a thickness that is substantially identical to that of the topmost metal layer.
